(19) United States
(12) Patent Application Publication
(10) Pub. No.: US 2026/0223663 A1
(43) Pub. Date: Jul. 30, 2026

(54) SEMICONDUCTOR DEVICE

(71) Applicant: Taiwan Semiconductor Manufacturing Company, Ltd., Hsinchu (TW)

(72) Inventors: Yao-Hong You, Hsinchu (TW); Yun-Hao Chen, Hsinchu (TW); Fa-Lun Chen, Hsinchu (TW); Tse-Hua Lu, Hsinchu (TW); Feng-Chi Hung, Hsinchu (TW); Jen-Cheng Liu, Hsinchu (TW)

(73) Assignee: Taiwan Semiconductor Manufacturing Company, Ltd., Hsinchu (TW)

(21) Appl. No.: 19/036,556

(22) Filed: Jan. 24, 2025

(51) Int. Cl. H01L 23/528; H01L 23/00; H01L 23/48; H01L 23/522; H01L 25/16; H10F 39/00; H10F 39/95

(52) U.S. Cl. CPC H10W 20/435; H10F 39/811; H10F 39/95; H10W 20/42; H10W 72/90; H10W 90/00; H10W 20/20

(57) ABSTRACT

A semiconductor device includes a first semiconductor chip and a second semiconductor chip. The first semiconductor chip includes a plurality of first conductive layers, and the second semiconductor chip is stacked to the first semiconductor chip. One of the first conductive layers includes a first local region and a second local region, the first local region has a first local metal density, the second local region has a second local metal density, and a difference between the first local metal density and the second local metal density is equal to or less than 5%.

### BACKGROUND

A semiconductor device includes at least one conductive layer. The conductive layers often have defects that cause some problem, such as leakage current, etc. For an image sensor device, the leakage current may cause ink problem and the white pixel problem.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a semiconductor device according to an embodiment of the present disclosure;

FIG. 2 illustrates a schematic diagram of a pixel array region PA of one of the first conductive layers of the first semiconductor chip of the semiconductor device in FIG. 1;

FIG. 3A illustrates a cross-sectional view of schematic diagram of the semiconductor device in FIG. 1 along a direction 3A-3A′; and

FIG. 3B illustrates an enlargement diagram of a local portion of the semiconductor device in FIG. 3A.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

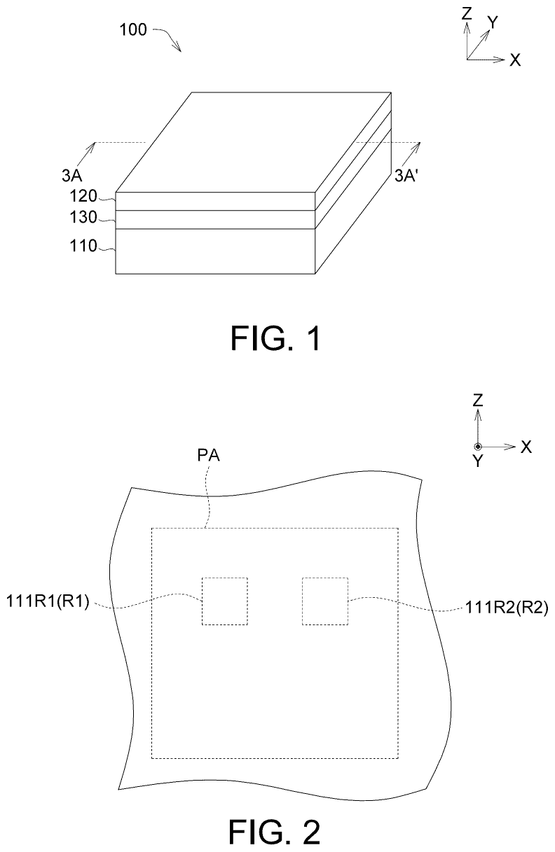

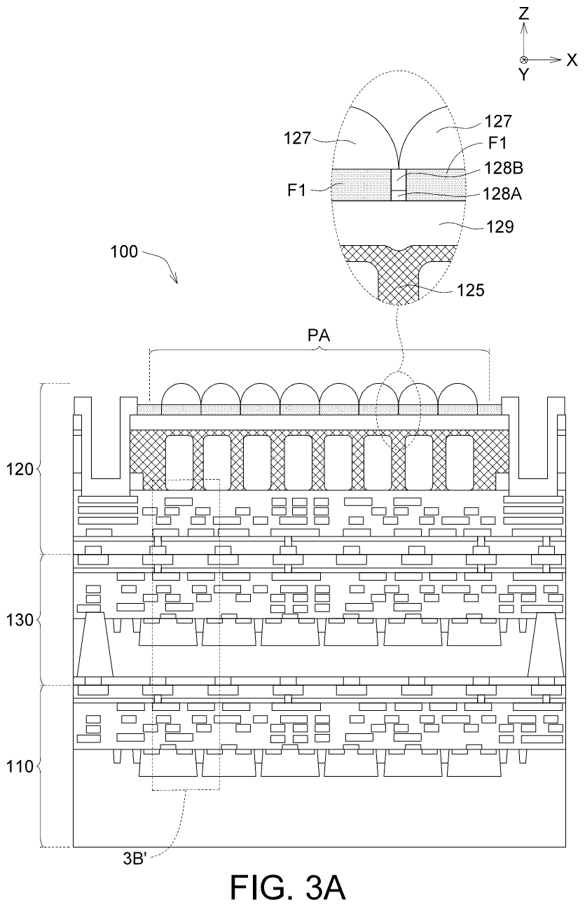

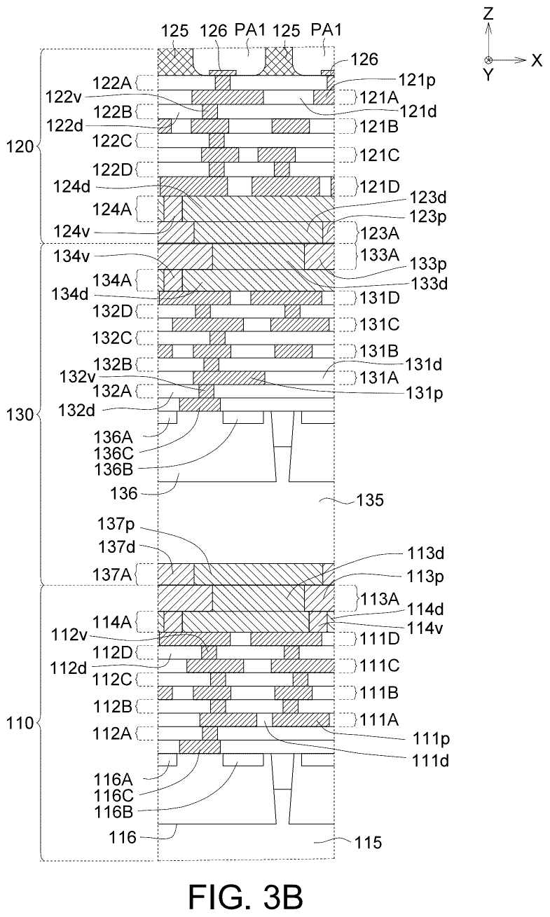

Referring to FIGS. 1, 2, 3A and 3B, FIG. 1 illustrates a schematic diagram of a semiconductor device 100 according to an embodiment of the present disclosure, FIG. 2 illustrates a schematic diagram of a pixel array region PA of one of the first conductive layers 111A to 11D of the first semiconductor chip 110 of the semiconductor device 100 in FIG. 1, FIG. 3A illustrates a cross-sectional view of schematic diagram of the semiconductor device 100 in FIG. 1 along a direction 3A-3A′, and FIG. 3B illustrates an enlargement diagram of a local portion 3B′ of the semiconductor device 100 in FIG. 3A.

The semiconductor device 100 is, for example, a semiconductor image sensor (CIS) device; however, the embodiment of the present disclosure is not limited to this.

As illustrated in FIGS. 1 to 3B, the semiconductor device 100 includes at least semiconductor chip (for example, a first semiconductor chip 110, a second semiconductor chip 120 and a third semiconductor chip 130). The first semiconductor chip 110 includes a plurality of first conductive layers 111A to 111D, and the second semiconductor chip 120 is stacked to the first semiconductor chip 110. One of the first conductive layers 111A to 111D includes a first local region 111R1 (as illustrated in FIG. 2) and a second local region 111R2 (as illustrated in FIG. 2), the first local region 111R1 has a first local metal density (MD) R1, the second local region 111R2 has a second local metal density R2, and a difference between the first local metal density R1 and the second local metal density R2 is equal to or less than 5%. As a result, it may reduce leakage current (for example, dark current) in the first conductive layers of the first semiconductor chip 110, thereby reducing contrast (for example, resolve the problem of the white pixel) on the display (that is, avoid ink issue). The greater the contrast between the two regions, the more serious the white pixel phenomenon is.

For example, in one of each of the first conductive layer 111A to 111D, the first local metal density R1 of the first local region 111R1 is, for example, 60%, and the second local metal density R2 of the second local region 111R2 may range between, for example, 55% and 65%, such as 55%, 56%, 57%, 58%, 59%, 60%, 61%, 62%, 63%, 64% or 65%.

The first conductive layers 111A to 111D may be stacked sequentially from a substrate 115 in a direction away from the substrate 115. The first conductive layers 111A to 111D may be referred to as M1 to M4. In the present embodiment, the number of the first conductive layers is four, or even greater or less. In another embodiment, the number of the first conductive layers may be one, two, three, five, six, seven, or more.

In an embodiment, the first local region 111R1 and the second local region 111R2 are arbitrary two regions of the first conductive layer. A difference between the first local metal density R1 and the second local metal density R2 of each of the first conductive layers 111A to 111D is equal to or less than 5%. As a result, it may reduce leakage current in the first conductive layers of the first semiconductor chip 110, thereby reducing contrast on the display (that is, avoid ink issue).

As illustrated in FIG. 3A to 3B, the first semiconductor chip 110 further includes a plurality of first conductive via layer 112A to 112D. Each first conductive via layer may be electrically with the corresponding first conductive layer. For example, one of the first conductive via layers electrically connects the adjacent two first conductive layers. One or each of the first conductive via layers 112A to 112D includes at least one conductive via 112v, and one or each of the first conductive layers 111A to 111D includes at least one conductive portion 111p (for example, trace, pad, etc.), wherein the conductive via 112v is electrically connected with the corresponding conductive portion 111p. The conductive via 112v is, for example, a through via. The conductive portion 111p and/or the conductive via 112v may be formed of a metal, for example, copper (Cu), coppered aluminum (AlCu), Tungsten (W), Tantalum nitride (TaN), etc. In addition, one of each of the first conductive layer 111A to 111D further includes a dielectric layer 111d, and the dielectric layer 111d covers a lateral surface of the conductive portion 111p. Similarly, one of each of the first conductive via layer 112A to 112E further includes a dielectric layer 112d, and the dielectric layer 112d covers a lateral surface of the conductive via 112v.

As illustrated in FIG. 3A to 3B, the first semiconductor chip 110 further a BPM (bonding pad metal) layer 113A and a BPV (bonding via metal) layer 114A. The BPM layer 113A includes at least one BPM (bonding pad metal) 113p, and the BPV layer 114A includes at least one BPV 114v, wherein the BPV 114v electrically connects the conductive portion 111p of the first conductive layer 111D with the BPM 113p of the BPM layer 113A. The first semiconductor chip 110 may be directly bonded to the third semiconductor chip 130 through the BPM 113p by using, for example, hybrid bonding technique. In addition, the BPM layer 113A includes the first local region 111R1 and the second local region 111R 2, the first local region 111R1 has a first local metal density R1, the second local region 111R2 has a second local metal density R2, and a difference between the first local metal density R1 and the second local metal density R2 is equal to or less than 5%. As a result, it may reduce leakage current in the first conductive layers of the first semiconductor chip 110, thereby reducing contrast on the display (that is, avoid ink issue).

As illustrated in FIG. 3A to 3B, the BPM layer 113A further includes a dielectric layer 113d, and the dielectric layer 113d covers a lateral surface of the conductive portion 111p. The BPV layer 114A further includes a dielectric layer 114d, and the dielectric layer 114d covers a lateral surface of the conductive portion 111p. The first semiconductor chip 110 may be directly bonded to the third semiconductor chip 130 through the BPM 113p and the dielectric layer 113d of the BPM layer 113A by using, for example, hybrid bonding technique.

As illustrated in FIG. 3A to 3B, in each or one of the first conductive layers 111A to 111D, the first local metal density R1 is the metal density of the area (for example, in XY plane) of the conductive portions 111p in the first local region 111R1 to the area (for example, in XY plane) of the first local region 111R1, and the second local metal density R2 is the metal density of the area (for example, in XY plane) of the conductive portions 111p in the second local region 111R2 to the area (for example, in XY plane) of the second local region 111R2. Similarly, in the BPM layer 113A, the first local metal density R1 is the metal density of the area (for example, in XY plane) of the BPM 113p in the first local region 111R1 to the area (for example, in XY plane) of the first local region 111R1, and the second local metal density R2 is the metal density of the area (for example, in XY plane) of the BPM 113p in the second local region 111R2 to the area (for example, in XY plane) of the second local region 111R2.

As illustrated in FIG. 3A to 3B, the first semiconductor chip 110 further includes the substrate 115 and at least one transistor 116. The transistor 116 is formed in or on the substrate 115. The substrate 115 is, for example, a portion of a silicon wafer. The transistor 116 includes a first electrode 116A, a second electrode 116B and a gate 116C, wherein the first electrode 116A is one of a source region and a drain region, the second electrode 116B is the other of the source region and the drain region. The gate 116C of the transistor 116 may be electrically connected with the conductive via 112v of the first conductive via layer 112A.

As illustrated in FIG. 3A to 3B, in one or each of the first conductive layer 111A to 111D, the first local metal density R1 and the second local metal density R2 may range between the 20% and 85%. In other words, the first conductive layer may have a metal density as low as 20% as long as the difference between the first local metal density R1 and the second local metal density R2 is equal to or less than 5%. Alternatively, the first conductive layer may have a metal density as high as 80% as long as the difference between the first local metal density R1 and the second local metal density R2 is equal to or less than 5%. Similarly, in BPM layer 113A, the first local metal density R1 and the second local metal density R2 may range between the 20% and 85%. In other words, the BPM layer 113A may have a metal density as low as 20% as long as the difference between the first local metal density R1 and the second local metal density R2 is equal to or less than 5%. Alternatively, the BPM layer 113A may have a metal density as high as 80% as long as the difference between the first local metal density R1 and the second local metal density R2 is equal to or less than 5%.

As illustrated in FIG. 3A to 3B, each of the first local metal density R1 and the second local metal density R2 of the topmost one of the first conductive layers 111A to 111D ranges between 75% and 80%. Furthermore, the conductive portions 111p of at least one of the first conductive layers 111C and 111D are, for example, power lines, and thus the conductive portions 111p has a wider width. As a result, in at least one of the first conductive layers 111C and 111D, each of the first local metal density R1 and the second local metal density R2 may range between 75% and 80%.

In addition, the first semiconductor chip 110 may be a logic chip, for example, an Application-Specific Integrated Circuit (ASIC). The first semiconductor chip 110 may process the signal from the third semiconductor chip 130 and/or the second semiconductor chip 120.

In another embodiment, each of the first conductive layers 111A to 111D has a metal density R, and each of the metal density R of adjacent two first conductive layers 111A to 111D is equal to or greater than 75%. As a result, it may reduce leakage current in the first conductive layers of the first semiconductor chip 110, thereby reducing contrast on the display (that is, avoid ink issue). The metal density R is the density in a region of the first conductive layer or an average density of the first conductive layer. In addition, when each of the metal densities R of adjacent two first conductive layers 111A to 111D is equal to or greater than 75%, the design of the metal densities R of the others of the first conductive layers 111A to 111D is not limited, wherein the others of the first conductive layers 111A to 111D are located, for example, below the top two first conductive layers 111C and 111D. For example, when each of the metal densities R of the top two first conductive layers 111C and 111D is equal to or greater than 75%, and the design of the metal densities R of the other first conductive layers 111A to 111B is not limited. For example, each of the others first conductive layers 111A and 111B may range between 20% and 85%.

As illustrated in FIG. 3A to 3B, the second semiconductor chip 120 is, for example, a photo-sensing chip. The photo-sensing chip may be a complementary metal-oxide semiconductor image sensor (CIS). The photo-sensing chip has an array of pixel sensors. A pixel sensor records incident radiation (e.g., visible light) using a photodetector, and facilitates digital readout of the recording with a plurality of pixel devices (e.g., a transfer transistor, a reset transistor, etc.) disposed on a front-side of a substrate. The pixel sensors include an array of photodetectors (e.g., a 2×2, 2×4, or 4×4 photodetector pixel sensor).

As illustrated in FIG. 3A to 3B, the second semiconductor chip 120 includes a plurality of second conductive layers 121A to 121D, a plurality of second conductive via layers 122A to 122D, a BPM layer 123A, a BPV layer 124A, a plurality of isolation structures 125, a plurality of sub-pixel regions PA1, a plurality of doping regions 126, a plurality of micro-lens 127, a plurality of conductive grid structures 128A, a plurality of dielectric grid structures 128B, a plurality of light filters F1 and an oxide layer 129.

In the present embodiment, the number of the second conductive layers is four, or even greater or less. In another embodiment, the number of the second conductive layers may be one, two, three, five, six, seven, or more.

As illustrated in FIG. 3A to 3B, one of the second conductive layers 121A to 121D includes a third local region (similar to the first local region 111R1 in FIG. 2) and a fourth local region (similar to the second local region 111R2 in FIG. 2), the third local region has a third local metal density, the fourth local region has a fourth local metal density, and a difference between the third local metal density and the fourth local metal density is equal to or less than 5%. As a result, it may reduce leakage current in the first conductive layers of the first semiconductor chip 120, thereby reducing contrast on the display (that is, avoid ink issue). The third local region and the fourth local region are arbitrary two regions of the second conductive layer.

In an embodiment, a difference between the third local metal density and the fourth local metal density of each of the second conductive layers 121A to 121D is equal to or less than 5%. As a result, it may reduce leakage current in the first conductive layers of the second semiconductor chip 120, thereby reducing contrast on the display (that is, avoid ink issue).

For example, in one of each of the second conductive layer 121A to 121D, the third local metal density of the third local region is, for example, 60%, and the fourth local metal density of the fourth local region may range between, for example, 55% and 65%, such as 55%, 56%, 57%, 58%, 59%, 60%, 61%, 62%, 63%, 64% or 65%.

The second conductive layer 121A to 121D may be stacked sequentially from the substrate 125 in a direction away from the substrate 125. The second conductive layer 121A to 121D may be referred to as M1 to M4. In the present embodiment, the number of the first conductive layers is four, or even greater or less. In another embodiment, the number of the first conductive layers may be one, two, three, five, six, seven, or more.

As illustrated in FIG. 3A to 3B, each second conductive via layer may be electrically with the corresponding second conductive layer. For example, one of the second conductive via layers electrically connects the adjacent two second conductive layers. One or each of the second conductive via layers 122A to 122D includes at least one conductive via 122v, and one or each of the second conductive layers 121A to 121D includes at least one conductive portion 121p (for example, trace, pad, etc.), wherein the conductive via 122v is electrically connected with the corresponding conductive portion 121p. The conductive via 122v is, for example, a through via. The conductive portion 121p and/or the conductive via 122v may be formed of a metal, for example, copper (Cu), coppered aluminum (AlCu), Tungsten (W), Tantalum nitride (TaN), etc. In addition, one of each of the second conductive layer 121A to 121D further includes a dielectric layer 121d, and the dielectric layer 121d covers a lateral surface of the conductive portion 121p. Similarly, one of each of the second conductive via layer 122A to 122D further includes a dielectric layer 122d, and the dielectric layer 122d covers a lateral surface of the conductive via 122v.

As illustrated in FIG. 3A to 3B, the BPM layer 123A includes at least one BPM 123p, and the BPV layer 124A includes at least one BPV 124v, wherein the BPV 124v electrically connects the conductive portion 121p of the second conductive layer 121D with the BPM 123p of the BPM layer 123A. The second semiconductor chip 120 may be directly bonded to the third semiconductor chip 130 through the BPM 123p by using, for example, hybrid bonding technique. In addition, the BPM layer 123A includes the third local region and the fourth local region, the third local region has a third local metal density, the fourth local region has a fourth local metal density, and a difference between the third local metal density and the fourth local metal density is equal to or less than 5%. As a result, it may reduce leakage current in the second conductive layers of the second semiconductor chip 120, thereby reducing contrast on the display (that is, avoid ink issue).

As illustrated in FIG. 3A to 3B, in each or one of the second conductive layers 121A to 121D, the third local metal density is the metal density of the area (for example, in XY plane) of the conductive portions 121p in the third local region to the area (for example, in XY plane) of the third local region, and the fourth local metal density is the metal density of the area (for example, in XY plane) of the conductive portions 121p in the fourth local region to the area (for example, in XY plane) of the fourth local region. Similarly, in the BPM layer 123A, the third local metal density is the metal density of the area (for example, in XY plane) of the BPM 123p in the third local region to the area (for example, in XY plane) of the third local region, and the fourth local metal density is the metal density of the area (for example, in XY plane) of the BPM 123p in the fourth local region to the area (for example, in XY plane) of the fourth local region.

As illustrated in FIG. 3A to 3B, the BPM layer 123A further includes a dielectric layer 123d, and the dielectric layer 123d covers a lateral surface of the conductive portion 123p. The BPV layer 124A further includes a dielectric layer 124d, and the dielectric layer 124d covers a lateral surface of the conductive portion 124v. The second semiconductor chip 120 may be directly bonded to the third semiconductor chip 130 through the BPM 123p and the dielectric layer 123d of the BPM layer 123A by using, for example, hybrid bonding technique.

As illustrated in FIG. 3A to 3B, in one or each of the second conductive layer 121A to 121D, the third local metal density and the fourth local metal density may range between the 20% and 85%. In other words, the second conductive layer may have a metal density as low as 20% as long as the difference between the third local metal density and the fourth local metal density is equal to or less than 5%. Alternatively, the second conductive layer may have a metal density as high as 80% as long as the difference between the third local metal density and the fourth local metal density is equal to or less than 5%. Similarly, in BPM layer 123A, the third local metal density and the fourth local metal density may range between the 20% and 85%. In other words, the BPM layer 123A may have a metal density as low as 20% as long as the difference between the third local metal density and the fourth local metal density is equal to or less than 5%. Alternatively, the BPM layer 123A may have a metal density as high as 80% as long as the difference between the third local metal density and the fourth local metal density is equal to or less than 5%.

As illustrated in FIG. 3A to 3B, each of the third local metal density and the fourth local metal density of the topmost one (in the direction of the second semiconductor chip 120 in FIG. 3A being inverted and the micro-lens 127 facing downward) of the second conductive layers 121A to 121D ranges between 75% and 80%. Furthermore, the conductive portions 121p of at least one of the second conductive layers 121C and 121D are, for example, power lines, and thus the conductive portions 121p has a wider width. As a result, in at least one of the second conductive layers 121C and 121D, each of the third local metal density and the fourth local metal density may range between 75% and 80%.

In another embodiment, each of the second conductive layers 121A to 121D has a metal density R, and each of the metal density R of adjacent two second conductive layers 121A to 121D is equal to or greater than 75%. As a result, it may reduce leakage current in the first conductive layers of the second semiconductor chip 120, thereby reducing contrast on the display (that is, avoid ink issue). In addition, when each of the metal densities of adjacent two second conductive layers 121A to 121D is equal to or greater than 75%, the design of the metal densities of the others of the second conductive layers 121A to 121D is not limited, wherein the others of the second conductive layers 121A to 121D are located, for example, below the top two second conductive layers 121C and 121D (in the direction of the second semiconductor chip 120 in FIG. 3A being inverted and the micro-lens 127 facing downward). For example, when each of the metal densities R of the top two second conductive layers 121C and 121D (in the direction of the second semiconductor chip 120 in FIG. 3A being inverted and the micro-lens 127 facing downward) is equal to or greater than 75%, and the design of the metal densities R of the other second conductive layers 121A to 121B is not limited. For example, each of the others second conductive layers 121A and 121B may range between 20% and 85%.

As illustrated in FIG. 3A to 3B, the pixel array region PA includes a plurality of the sub-pixel regions (or photodetectors) PA1. The pixel array regions PA are a portion of the silicon wafer. Through the photoelectric effect, electrons may be generated in the sub-pixel region PA1 when the sub-pixel region PA1 is illuminated by light. One of the sub-pixel regions PA1 may sense one type of light color, such as red, green or blue, and different two of the sub-pixel regions PA1 may sense different types of light color. In addition, the pixel array region PA and a conductive structure overlap in a thickness direction (for example, Z-axis), wherein the conductive structure includes, for example, the first conductive layer 111A to 111D, the BPM layer 113A, the second conductive layer 121A to 121D and the BPM layer 123A.

As illustrated in FIG. 3A to 3B, the isolation structures 125 may surround the sub-pixel regions PA1 for isolating adjacent two sub-pixel regions PA1. In an embodiment, the isolation structure 125 is, for example, a DTI (Deep trench isolation), or FDTI (Full Deep trench isolation). The isolation structures 125 may be a single-layered structure or a multi-layered structure.

As illustrated in FIG. 3A to 3B, the doping region 126 may be formed within the sub-pixel region PA1 by using, for example, implanting, etc. The doping region 126 may serve as a drain or a source of an image sensing unit. In an embodiment, the doping region 126 may be drain region, for example, N-type doping region.

As illustrated in FIG. 3A to 3B, each micro-lens 127 is formed over the corresponding light filter F1. A plurality of light filters F1 is disposed in the plurality of openings defined by the sidewalls of the conductive grid structure 128A and the dielectric grid structure 128B. The light filters F1 are configured to transmit specific wavelengths of incident light while blocking other wavelengths of incident light. A plurality of micro-lenses 127 overlies the light filters F1 and is configured to focus the incident light towards the sub-pixel regions PA1. In some embodiments, the light filters F1 and the micro-lenses 127 may be deposited by, for example, CVD, PVD, ALD, or some other suitable deposition or growth process. Each micro-lens 127 overlies the corresponding light filter F1 and is configured to focus the incident light towards the sub-pixel region PA1. The oxide layer 129 is formed over the isolation structure 125. The oxide layer 129 may, for example, be or includes an oxide, such as silicon dioxide, or the like. In some embodiments, the oxide layer 129 is formed by a PVD process, a CVD process, an ALD process, or some other suitable growth or deposition process. In another embodiment, the oxide layer 129 may be ARC (Anti-reflective coating). The conductive grid structure 128A is formed over the oxide layer 129 and the dielectric grid structure 128B is formed over the conductive grid structure 128A.

As illustrated in FIG. 3A to 3B, the conductive grid structure 128A overlies the oxide layer 129 and the dielectric grid structure 128A overlies the conductive grid structure 128B. The conductive grid structure 128A and the dielectric grid structure 128B include sidewalls that define a plurality of openings overlying the sub-pixel regions PA1. In various embodiments, the conductive grid structure 128A includes one or more metal layers that is/are configured to reduce cross-talk between adjacent sub-pixel regions PA1, thereby increasing optical isolation of the image sensor. In addition, the dielectric grid structure 128B is configured to direct light to the sub-pixel regions PA1 by total internal reflection such that cross-talk is further reduced and a quantum efficiency of the sub-pixel regions PA1 is increased.

As illustrated in FIGS. 3A to 3B, the third semiconductor chip 130 includes a plurality of third conductive layers 131A to 131D, a plurality of third conductive via layers 132A to 132D, a BPM layer 133A, a BPV layer 134A, a substrate 135, at least one transistor 136 and a BPM layer 137A.

In the present embodiment, the number of the third conductive layers is four, or even greater or less. In another embodiment, the number of the third conductive layers may be one, two, three, five, six, seven, or more.

As illustrated in FIG. 3A to 3B, one of the third conductive layers 131A to 131D includes a fifth local region (similar to the first local region 111R1 in FIG. 2) and a sixth local region (similar to the second local region 111R2 in FIG. 2), the fifth local region has a fifth local metal density, the sixth local region has a sixth local metal density, and a difference between the fifth local metal density and the sixth local metal density is equal to or less than 5%. As a result, it may reduce leakage current in the first conductive layers of the third semiconductor chip 130, thereby reducing contrast on the display (that is, avoid ink issue). The fifth local region and the sixth local region are arbitrary two regions of the second conductive layer.

In the present embodiment, the number of the third conductive layers is four, or even greater or less. In another embodiment, the number of the third conductive layers may be one, two, three, five, six, seven, or more.

As illustrated in FIG. 3A to 3B, each third conductive via layer may be electrically with the corresponding third conductive layer. For example, one of the third conductive via layers electrically connects the adjacent two third conductive layers. One or each of the third conductive via layers 132A to 132D includes at least one conductive via 132v, and one or each of the third conductive layers 131A to 131D includes at least one conductive portion 131p (for example, trace, pad, etc.), wherein the conductive via 132v is electrically connected with the corresponding conductive portion 131p. The conductive via 132v is, for example, a through via. The conductive portion 131p and/or the conductive via 132v may be formed of a metal, for example, copper (Cu), coppered aluminum (AlCu), Tungsten (W), Tantalum nitride (TaN), etc. In addition, one of each of the second conductive layer 131A to 131D further includes a dielectric layer 131d, and the dielectric layer 131d covers a lateral surface of the conductive portion 131p. Similarly, one of each of the third conductive via layer 132A to 132D further includes a dielectric layer 132d, and the dielectric layer 132d covers a lateral surface of the conductive via 132v.

As illustrated in FIG. 3A to 3B, the BPM layer 133A includes at least one BPM 133p, and the BPV layer 134A includes at least one BPV 134v, wherein the BPV 134v electrically connects the conductive portion 131p of the third conductive layer 131D with the BPM 133p of the BPM layer 133A. The third semiconductor chip 130 may be directly bonded to the second semiconductor chip 120 through the BPM 133p by using, for example, hybrid bonding technique. In addition, the BPM layer 133A includes the fifth local region and the sixth local region, the fifth local region has a fifth local metal density, the sixth local region has a sixth local metal density, and a difference between the fifth local metal density and the sixth local metal density is equal to or less than 5%. As a result, it may reduce leakage current in the third conductive layers of the third semiconductor chip 130, thereby reducing contrast on the display (that is, avoid ink issue).

As illustrated in FIG. 3A to 3B, in each or one of the third conductive layers 131A to 131D, the fifth local metal density is the metal density of the area (for example, in XY plane) of the conductive portions 131p in the fifth local region to the area (for example, in XY plane) of the fifth local region, and the sixth local metal density is the metal density of the area (for example, in XY plane) of the conductive portions 131p in the sixth local region to the area (for example, in XY plane) of the sixth local region. Similarly, in the BPM layer 133A, the fifth local metal density is the metal density of the area (for example, in XY plane) of the BPM 133p in the fifth local region to the area (for example, in XY plane) of the fifth local region, and the sixth local metal density is the metal density of the area (for example, in XY plane) of the BPM 133p in the sixth local region to the area (for example, in XY plane) of the sixth local region.

As illustrated in FIG. 3A to 3B, the BPM layer 133A further includes a dielectric layer 133d, and the dielectric layer 133d covers a lateral surface of the conductive portion 133p. The BPV layer 134A further includes a dielectric layer 134d, and the dielectric layer 134d covers a lateral surface of the conductive portion 134v. The third semiconductor chip 130 may be directly bonded to the second semiconductor chip 120 through the BPM 133p and the dielectric layer 133d of the BPM layer 133A by using, for example, hybrid bonding technique.

As illustrated in FIG. 3A to 3B, in one or each of the third conductive layer 131A to 131D, the fifth local metal density and the sixth local metal density may range between the 20% and 85%. In other words, the third conductive layer may have a metal density as low as 20% as long as the difference between the fifth local metal density and the sixth local metal density is equal to or less than 5%. Alternatively, the third conductive layer may have a metal density as high as 80% as long as the difference between the fifth local metal density and the sixth local metal density is equal to or less than 5%. Similarly, in BPM layer 133A, the fifth local metal density and the sixth local metal density may range between the 20% and 85%. In other words, the BPM layer 133A may have a metal density as low as 20% as long as the difference between the fifth local metal density and the sixth local metal density is equal to or less than 5%. Alternatively, the BPM layer 133A may have a metal density as high as 80% as long as the difference between the fifth local metal density and the sixth local metal density is equal to or less than 5%.

As illustrated in FIG. 3A to 3B, each of the fifth local metal density and the sixth local metal density of the topmost one of the third conductive layers 131A to 131D ranges between 75% and 80%. Furthermore, the conductive portions 131p of at least one of the third conductive layers 131C and 131D are, for example, power lines, and thus the conductive portions 131p has a wider width. As a result, in at least one of the third conductive layers 131C and 131D, each of the fifth local metal density and the sixth local metal density may range between 75% and 80%.

In another embodiment, each of the third conductive layers 131A to 131D has a metal density R, and each of the metal density R of adjacent two third conductive layers 131A to 131D is equal to or greater than 75%. As a result, it may reduce leakage current in the first conductive layers of the third semiconductor chip 130, thereby reducing contrast on the display (that is, avoid ink issue). In addition, when each of the metal densities of adjacent two third conductive layers 131A to 131D is equal to or greater than 75%, the design of the metal densities of the others of the third conductive layers 131A to 131D is not limited, wherein the others of the third conductive layers 131A to 131D are located, for example, below the top two third conductive layers 131C and 131D. For example, when each of the metal densities R of the top two third conductive layers 131C and 131D is equal to or greater than 75%, and the design of the metal densities R of the other third conductive layers 131A to 131B is not limited. For example, each of the others third conductive layers 131A and 131B may range between 20% and 85%.

As illustrated in FIG. 3A to 3B, the transistor 136 is formed in or on the substrate 135. The substrate 135 is, for example, a portion of a silicon wafer. The transistor 136 includes a first electrode 136A, a second electrode 136B and a gate 136C, wherein the first electrode 136A is one of a source region and a drain region, the second electrode 136B is the other of the source region and the drain region. The gate 136C of the transistor 136 may be electrically connected with the conductive via 132v of the first conductive via layer 132A.

As illustrated in FIG. 3A to 3B, the doping region 126 of the second semiconductor chip 120 may be electrically connected with the transistor 136 through the second conductive layers 121A to 121D, the second conductive via layers 122A to 122D, the BPM layer 123A and the BPV layer 124A of the second semiconductor chip 120 and the third conductive layers 131A to 131D, the third conductive via layers 132A to 132D, the BPM layer 133A and the BPV layer 134A of the third semiconductor chip 130.

As illustrated in FIG. 3A to 3B, the BPM layer 137A is formed on the substrate 135, and includes at least one conductive portion 137p and a dielectric layer 137d, wherein the dielectric layer 137d covers a lateral surface of the conductive portion 137p. The third semiconductor chip 130 may be directly bonded to the first semiconductor chip 110 through the BPM 137p and the dielectric layer 137d by using, for example, hybrid bonding technique. The transistor 136 may be electrically connected with the transistor 116 through the BPM layer 137A, the first conductive layer 111A to 111D, the first conductive via layer 112A to 112D, the BPM layer 113A and the BPV layer 114A.

In another embodiment, the semiconductor device 100 may omit the third semiconductor chip 130, and the first semiconductor chip 110 and the second semiconductor chip 120 are directly bonded to each other by using, for example, hybrid bonding technique.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a plurality semiconductor chips which are stacked to each other. One of each of the semiconductor chips includes a plurality of conductive layers. In a first embodiment, in one or each of the conductive layers, two local regions has two local metal density respectively, and a difference between the two local metal density is equal to or less than 5%. In a second embodiment, each of the conductive layers has a metal density, and the metal densities of adjacent two first conductive layers may be equal to or greater than 75%. As a result, by uniforming at least one of the conductive layers, it may reduce leakage current (for example, a dark current) in the conductive layers of the semiconductor chip, thereby reducing contrast (for example, resolve the problem of the white pixel) on the display (that is, avoid ink issue). In addition, through the design of the metal density, the formation for each or one of at least one semiconductor chip of the semiconductor device does not need extra mask and/or manufacturing process.

Example embodiment 1: a semiconductor device includes a first semiconductor chip and a second semiconductor chip. The first semiconductor chip includes a plurality of first conductive layers. The second semiconductor chip is stacked to the first semiconductor chip. One of the first conductive layers includes a first local region and a second local region, the first local region has a first local metal density, the second local region has a second local metal density, and a difference between the first local metal density and the second local metal density is equal to or less than 5%

Example embodiment 2 based on Example embodiment 1: a difference between the first local metal density and the second local metal density of each of the first conductive layers is equal to or less than 5%.

Example embodiment 3 based on Example embodiment 1: the first local metal density and the second local metal density ranges between the 20% and 85%.

Example embodiment 4 based on Example embodiment 1: each of the first local metal density and the second local metal density of the topmost one of the first conductive layers ranges between 75% and 80%.

Example embodiment 5 based on Example embodiment 4: each the third local metal density and the fourth local metal density ranges between the 20% and 85%.

Example embodiment 6 based on Example embodiment 1: the second semiconductor chip includes a plurality of second conductive layers, one of the second conductive layers includes a third local region and a fourth local region, the third region has a third local metal density, the fourth local region has a fourth local metal density, and a difference between the third local metal density and the fourth local metal density is equal to or less than 5%.

Example embodiment 7 based on Example embodiment 6: each of the third local metal density and the fourth local metal density of the topmost one of the second conductive layers ranges between 75% and 80%.

Example embodiment 8 based on Example embodiment 1: the first semiconductor chip is a logic chip, and the second semiconductor chip is a photo-sensing chip.

Example embodiment 9: a semiconductor device includes a first semiconductor chip and a second semiconductor chip. The first semiconductor chip includes a plurality of first conductive layers. The second semiconductor chip is stacked to the first semiconductor chip. Each of the first conductive layers has a metal density, and each of the metal densities of adjacent two first conductive layers is equal to or greater than 75%.

Example embodiment 10 based on Example embodiment 9: the adjacent two first conductive layers are the top two first conductive layers.

Example embodiment 11 based on Example embodiment 9: each of the others of the first conductive layers ranges between 20% and 85%.

Example embodiment 12 based on Example embodiment 9: the adjacent two first conductive layers are the top two first conductive layers, the first conductive layers which are located below the top two first conductive layers each has the metal density ranging between 20% and 85%.

Example embodiment 13 based on Example embodiment 9: the second semiconductor chip includes a plurality of second conductive layers each of the second metal densities of adjacent two second conductive layers is greater than 75%.

Example embodiment 14 based on Example embodiment 13: the adjacent two second conductive layers are the top two second conductive layers.

Example embodiment 15 based on Example embodiment 13: each of the others of the second conductive layers ranges 20% and 85%.

Example embodiment 16 based on Example embodiment 13: the adjacent two second conductive layers are the top two second conductive layers, the second conductive layers which are located below the top two second conductive layers each has the second metal density ranges 20% and 85%.

### Example Embodiment 17: a Semiconductor Device Includes a First

semiconductor chip, a second semiconductor chip and a third semiconductor chip. The first semiconductor chip includes a plurality of first conductive layers. The second semiconductor chip is stacked to the first semiconductor chip. The third semiconductor chip is disposed between the first semiconductor chip and the second semiconductor chip. One of the first conductive layers includes a first local region and a second local region, the first local region has a first local metal density, the second local region has a second local metal density, and a difference between the first local metal density and the second local metal density is equal to or less than 5%.

Example embodiment 18 based on Example embodiment 17: the first semiconductor chip is directly bonded to the third semiconductor chip.

Example embodiment 19 based on Example embodiment 17: the first local metal density and the second local metal density ranges between the 20% and 85%.

Example embodiment 20 based on Example embodiment 17: each of the first local metal density and the second local metal density of the topmost one of the first conductive layers ranges between 75% and 80%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor chip comprising a plurality of first conductive layers; and
a second semiconductor chip stacked to the first semiconductor chip;
wherein one of the first conductive layers comprises a first local region and a second local region, the first local region has a first local metal density, the second local region has a second local metal density, and a difference between the first local metal density and the second local metal density is equal to or less than 5%.

2. The semiconductor device as claimed in claim 1, wherein a difference between the first local metal density and the second local metal density of each of the first conductive layers is equal to or less than 5%.

3. The semiconductor device as claimed in claim 1, wherein the first local metal density and the second local metal density ranges between the 20% and 85%.

4. The semiconductor device as claimed in claim 1, wherein each of the first local metal density and the second local metal density of the topmost one of the first conductive layers ranges between 75% and 80%.

5. The semiconductor device as claimed in claim 4, wherein each the third local metal density and the fourth local metal density ranges between the 20% and 85%.

6. The semiconductor device as claimed in claim 1, wherein the second semiconductor chip comprising a plurality of second conductive layers, one of the second conductive layers comprises a third local region and a fourth local region, the third region has a third local metal density, the fourth local region has a fourth local metal density, and a difference between the third local metal density and the fourth local metal density is equal to or less than 5%.

7. The semiconductor device as claimed in claim 6, wherein each of the third local metal density and the fourth local metal density of the topmost one of the second conductive layers ranges between 75% and 80%.

8. The semiconductor device as claimed in claim 1, the first semiconductor chip is a logic chip, and the second semiconductor chip is a photo-sensing chip.

9. A semiconductor device, comprising:
a first semiconductor chip comprising a plurality of first conductive layers; and
a second semiconductor chip stacked to the first semiconductor chip;
wherein each of the first conductive layers has a metal density, and each of the metal densities of adjacent two first conductive layers is equal to or greater than 75%.

10. The semiconductor device as claimed in claim 9, wherein the adjacent two first conductive layers are the top two first conductive layers.

11. The semiconductor device as claimed in claim 9, wherein each of the others of the first conductive layers ranges between 20% and 85%.

12. The semiconductor device as claimed in claim 9, wherein the adjacent two first conductive layers are the top two first conductive layers, the first conductive layers which are located below the top two first conductive layers each has the metal density ranging between 20% and 85%.

13. The semiconductor device as claimed in claim 9, wherein the second semiconductor chip comprises a plurality of second conductive layers each of the second metal densities of adjacent two second conductive layers is greater than 75%.

14. The semiconductor device as claimed in claim 13, wherein the adjacent two second conductive layers are the top two second conductive layers.

15. The semiconductor device as claimed in claim 13, wherein each of the others of the second conductive layers ranges 20% and 85%.

16. The semiconductor device as claimed in claim 13, wherein the adjacent two second conductive layers are the top two second conductive layers, the second conductive layers which are located below the top two second conductive layers each has the second metal density ranges 20% and 85%.

17. A semiconductor device, comprising:
a first semiconductor chip comprising a plurality of first conductive layers;
a second semiconductor chip stacked to the first semiconductor chip;
a third semiconductor chip disposed between the first semiconductor chip and the second semiconductor chip;
wherein one of the first conductive layers comprises a first local region and a second local region, the first local region has a first local metal density, the second local region has a second local metal density, and a difference between the first local metal density and the second local metal density is equal to or less than 5%.

18. The semiconductor device as claimed in claim 17, wherein the first semiconductor chip is directly bonded to the third semiconductor chip.

19. The semiconductor device as claimed in claim 17, wherein the first local metal density and the second local metal density ranges between the 20% and 85%.

20. The semiconductor device as claimed in claim 17, wherein each of the first local metal density and the second local metal density of the topmost one of the first conductive layers ranges between 75% and 80%.
